(19) United States
(12) Patent Application Publication
(10) Pub. No.: US 2009/0052136 A1
(43) Pub. Date: Feb. 26, 2009

(54) HEAT DISSIPATION DEVICE

(75) Inventor: Chao-Tsai Chung, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ASUSTeK COMPUTER INC., Taipei (TW)

(21) Appl. No.: 12/193,048

(22) Filed: Aug. 18, 2008

(30) Foreign Application Priority Data
Aug. 20, 2007 (TW) 96130680

(51) Int. Cl. H05K 7/20

(52) U.S. Cl. 361/702

(57) ABSTRACT

A heat dissipation device for dissipating heat of a heat source is provided. The heat dissipation device includes a first heat dissipation unit having a heat sink and a tank, a second heat dissipation unit, a pump, and a plurality of tubes. The heat sink has a heat dissipation base, and the tank is adapted to contain a heat exchange medium and has a liquid inlet, a liquid outlet and an opening. The heat sink is disposed at the tank. The heat dissipation base passes through the opening, and it contacts the heat source. The tubes connect the liquid inlet, the liquid outlet, the second heat dissipation unit and the pump to form a closed circulation flow loop. The heat exchange medium is driven to flow in the closed circulation flow loop by the pump, and the second heat dissipation unit is adapted to cool the heat exchange medium.

### CROSS-REFERENCE TO RELATED APPLICATION

This application claims the priority benefit of Taiwan application serial no. 96130680, filed on Aug. 20, 2007. The entirety of the above-mentioned patent application is hereby incorporated by reference herein and made a part of specification.

### BACKGROUND OF THE INVENTION

1. Field of the Invention

The invention relates to a heat dissipation device and, more particularly, to a heat dissipation device disposed in a computer.

2. Description of the Related Art

In recent years, along with the enormous progress of the science and technology, the operating speed of a computer continuously increases, and power consumption rates of electronic elements in a computer also increase. To prevent the electronic elements in the computer host from being overheated and loosing effectiveness temporarily or permanently, it is important to effectively remove the heat of the electronic elements in the computer.

FIG. 1 is a schematic diagram showing a conventional heat dissipation device. As shown in FIG. 1, a heat dissipation device 100 includes a heat dissipation base 110, a tank 120, a heat exchanger 130, a pump 140 and a plurality of tubes 150. The heat dissipation base 110 is disposed on a heat source 10 and has a heat dissipation flow channel 112. The tank 120 is used to contain a heat exchange medium, and the tubes 150 connect the heat dissipation flow channel 112, the tank 120, the heat exchanger 130 and the pump 140 to form a closed circulation flow channel loop. The heat exchange medium in the tank 120 can be driven to flow in the closed circulation flow loop by the pump 140. In this way, the heat exchange medium is driven to flow into the heat dissipation flow loop 112 by the pump 140, and it can remove the heat that is transmitted to the heat dissipation base 110 from the heat source 10 via a heat exchange process. Then, the heat exchange medium flows into the heat exchanger 130 via the tubes 150 to dissipate the heat that is removed from the heat dissipation base 110 to the ambient environment via the heat exchanger 130.

The length of the heat dissipation flow channel 112 is limited, and the heat dissipation base 110 and the heat exchange medium have little heat exchange area. Therefore, when the heat exchange medium flows through the heat dissipation flow channel 112, the heat exchange medium cannot exchanges heat with the heat dissipation base 110 effectively, and it is difficult for the heat exchange medium to dissipate the heat that is transmitted to the heat dissipation base 110 from the heat source 10, which causes the heat dissipation performance of the heat dissipation device 100 to be bad.

### BRIEF SUMMARY OF THE INVENTION

The invention provides a heat dissipation device having preferred heat dissipation performance.

The invention provides a heat dissipation device for dissipating heat of a heat source. The heat dissipation device includes a first heat dissipation unit, a second heat dissipation unit, a pump and a plurality of tubes. The first heat dissipation unit has a heat sink and a tank. The heat sink has a heat dissipation base, and the tank is adapted to contain a heat exchange medium and has a liquid inlet, a liquid outlet and an opening. The heat sink is disposed in the tank, and the heat dissipation base is tightly-fitted with the opening and contacts the heat source to dissipate the heat of the heat source. The tubes connect the liquid inlet, the liquid outlet, the second heat dissipation unit and the pump to form a closed circulation flow loop. The pump can drive the heat exchange medium to flow in the closed circulation flow loop, and the second heat dissipation unit is adapted to cool the heat exchange medium.

In one embodiment of the invention, the first heat dissipation unit further includes an impeller for driving the heat exchange medium that flows into the tank from the liquid inlet to uniformly flow through the heat sink.

In one embodiment of the invention, the tank includes a main body and a cover, the heat sink is disposed in the main body, and the cover covers the main body.

In one embodiment of the invention, the tank further includes a first seal disposed between the cover and the main body.

In one embodiment of the invention, the tank further includes a second seal disposed between the opening and the heat dissipation base.

In one embodiment of the invention, the second heat dissipation unit is a heat exchanger.

In one embodiment of the invention, the heat dissipation device further includes a fan disposed at the second heat dissipation unit.

In one embodiment of the invention, the heat dissipation device further includes a bracket and a plurality of fasteners. The fasteners pass through the bracket and the heat dissipation base to allow the bracket to be assembled to the first heat dissipation unit, and the first heat dissipation unit is fixed on the heat source via the bracket.

The invention further provides a heat dissipation device for dissipating heat of a heat source. The heat dissipation device includes a heat sink and a tank. The heat sink has a heat dissipation base, and the tank is adapted to contain a heat exchange medium. The tank has a liquid inlet, a liquid outlet and an opening. The heat sink is disposed in the tank, and the heat exchange medium is adapted to flow into the tank from the liquid inlet, flow through the heat sink and flow out of the tank from the liquid outlet. The heat dissipation base is tightly-fitted with the opening and contacts the heat source to dissipate the heat of the heat source.

In one embodiment of the invention, the first heat dissipation unit further includes an impeller for driving the heat exchange medium that flows into the tank from the liquid inlet to uniformly flow through the heat sink.

In one embodiment of the invention, the tank includes a main body and a cover, the heat sink is disposed in the main body, and the cover covers the main body.

In one embodiment of the invention, the tank further includes a first seal disposed between the cover and the main body.

In one embodiment of the invention, the tank further includes a second seal disposed between the opening and the heat dissipation base.

In one embodiment of the invention, the heat dissipation device further includes a bracket and a plurality of fasteners. The fasteners pass through the bracket and the heat dissipation base to allow the bracket to be assembled to the first heat dissipation unit, and the first heat dissipation unit is fixed on the heat source via the bracket.

In the invention, the heat sink is disposed in the tank for containing the heat exchange medium, and the heat exchange medium uniformly flows through the heat sink to effectively dissipate the heat that is transmitted to the heat sink from the heat source. The heat sink and the heat exchange medium of the invention have a larger heat exchange area, and therefore, the heat transmitted to the heat sink can be effectively removed by the heat exchange medium after the heat exchange medium exchanges heat with the heat sink. Compared with the convention technology, the heat dissipation device of the invention has preferred heat dissipation performance.

These and other features, aspects, and advantages of the present invention will become better understood with regard to the following description, appended claims, and accompanying drawings.

### BRIEF DESCRIPTION OF THE SEVERAL VIEWS OF THE DRAWINGS

FIG. 1 is a schematic diagram showing a conventional heat dissipation device.

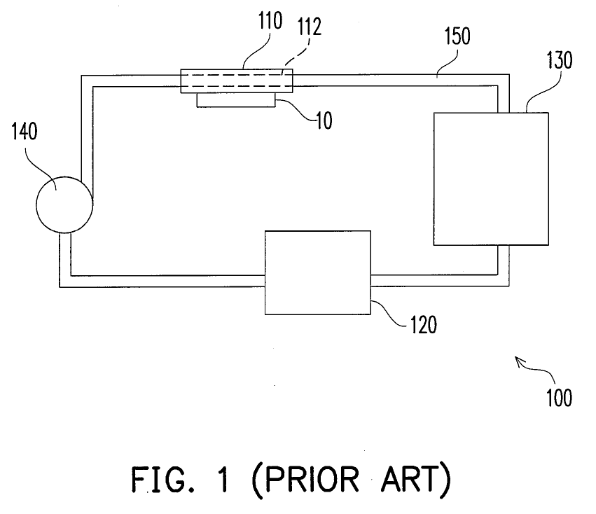

FIG. 2 is a schematic diagram showing a heat dissipation device of one embodiment of the invention.

FIG. 3 is an exploded diagram showing a first heat dissipation unit and a bracket of one embodiment of the invention.

### DETAILED DESCRIPTION OF THE EMBODIMENTS

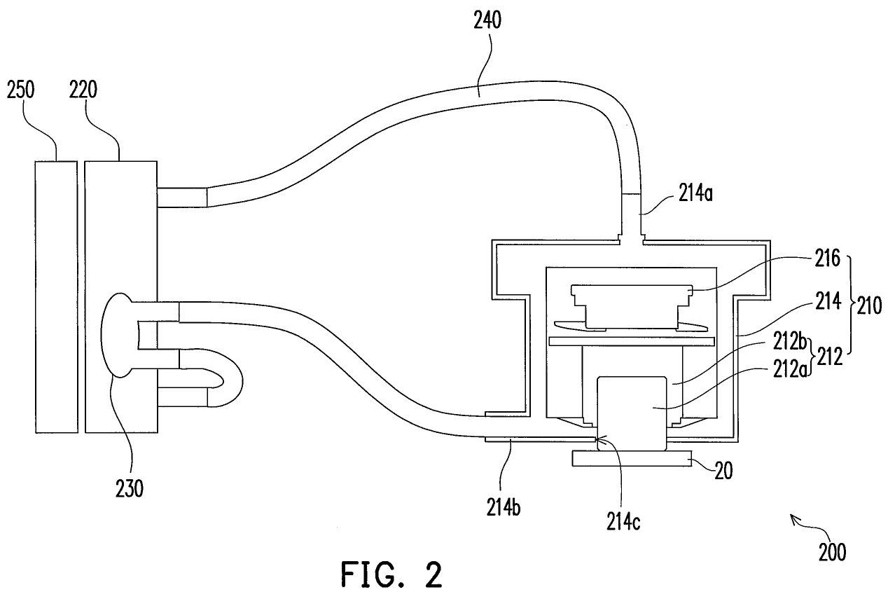

FIG. 2 is a schematic diagram showing a heat dissipation device of one embodiment of the invention. As shown in FIG. 2, a heat dissipation device 200 of the embodiment is adapted to dissipate the heat of a heat source 20. The heat dissipation device 200 includes a first heat dissipation unit 210, a second heat dissipation unit 220, a pump 230 and a plurality of tubes 240. In the embodiment, the first heat dissipation unit 210 mostly consists of a heat sink 212 and a tank 214 for containing a heat exchange medium. The heat sink 212 is disposed in the tank 214, and the heat sink 212 is adapted to dissipate the heat of the heat source 20. Specifically, in the embodiment, the tank 214 has a liquid inlet 214a, a liquid outlet 214b and an opening 214c. The heat dissipation base 212a of the heat sink 212 passes through the opening 214c, and the heat dissipation base 212a is tightly-fitted with the opening 214c. In this way, the first heat dissipation unit 210 can be disposed on the heat source 20 to dissipate the heat of the heat source 20.

The tubes 240 connect the tank 214, the second heat dissipation unit 220 and the pump 230 to form a closed circulation flow loop, and the pump 230 can drive the heat exchange medium contained in the tank 214 to flow in the closed circulation flow loop to dissipate the heat transmitted to the heat sink 212 from the heat source 20. In detail, the tubes 240 connected to the tank 214 are connected to the liquid inlet 214a and the liquid outlet 214b of the tank 214, respectively, and therefore, the heat exchange medium is driven to flow into the tank 214 from the liquid inlet 214a by the pump 230. In the embodiment, an impeller 216 may be disposed in the tank 214, and it can allow the heat exchange medium that flows into the tank 214 from the liquid inlet 214a to uniformly flow through the heat sink 212 to dissipate the heat transmitted from the heat source 20 to the heat sink 212. The impeller 216 also can increase the flow rate of the heat exchange medium that flows through the heat sink 212. In this way, the heat exchange medium can dissipate much heat in a unit interval, and the heat sink has preferred heat dissipation performance.

In the embodiment, the heat sink 212 may be, for example, an extrusion heat sink having a plurality of fins 212b or a heat sink having a larger heat dissipation area. Since the fins 212b and the heat exchange medium have a larger contact area, when the heat exchange medium uniformly flows through each fin 212b of the heat sink 212, the heat exchange medium can exchange heat with each fin 212b effectively to remove the heat transmitted from the heat source 20 to the heat sink 212. After the heat exchange medium removes the heat transmitted from the heat source 20 to the heat sink 212, the heat exchange medium is driven to successively flow out of the tank 214 by the impeller 216. After the heat exchange medium flows out of the tank 214 from the liquid outlet 214b, it flows into the second heat dissipation unit 220 such as a heat exchanger via the tube 240 to dissipate the heat that is removed from the heat sink 212 to the ambient environment via the heat exchanger further to decrease the temperature of the heat exchange medium. In the embodiment, a fan 250 may be disposed on the heat exchanger to effectively dissipate the heat that the heat exchange medium absorbs from the heat sink 212 in a forced convection mode.

Specifically, the temperature of the heat exchange medium rises after the heat exchange medium exchanges heat with the heat sink 212. The heat exchange medium whose temperature rises is driven by the pump 230 to flow into the second heat dissipation unit 220 to exchange heat with the ambient environment further to decrease the temperature. The heat exchange medium whose temperature decreases is driven by the pump 230 to flow into the tank 214 to exchange heat with the heat sink 212 disposed in the tank 214 again. After the heat exchange medium exchanges heat with the heat sink 212, it flows into the heat exchanger 220 to exchange heat with the ambient environment to decrease the temperature. Therefore, after the heat exchange medium flows into the tank 214 again, the temperature drops. The heat exchange medium effectively dissipates the heat transmitted from the heat source 20 to the heat sink 212, and then the heat dissipation device 200 of the embodiment has preferred heat dissipation performance.

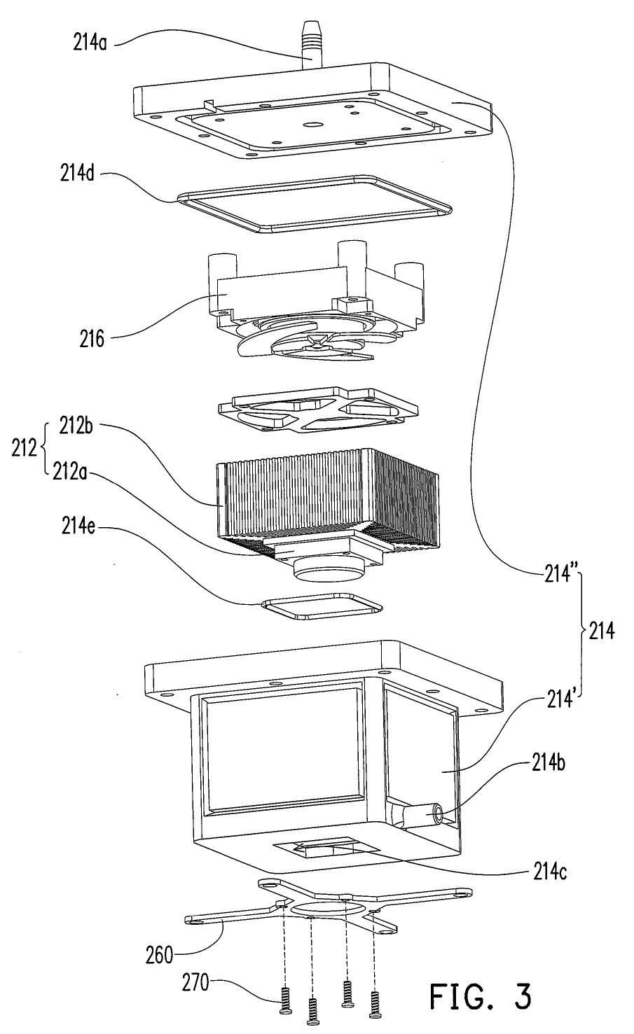

In the embodiment, the first heat dissipation unit 210 is illustrated in detail herein below. FIG. 3 is an exploded diagram showing a first heat dissipation unit and a bracket of one embodiment of the invention. As shown in FIG. 3, in the first heat dissipation unit of the embodiment, the tank 214 consists of, for example, a main body 214′ and a cover 214″ covering the main body 214′. The liquid inlet 214a is disposed at the cover 214″, the liquid outlet 214b and an opening 214c are disposed at the main body 214′, and the heat sink 212 is disposed in the main body 214′. In the embodiment, a first seal 214d is disposed in the tank 214 and between the cover 214″ and the main body 214′, and a second seal 214e is disposed in the tank 214 and between the opening 214c and the heat dissipation base 212a. Therefore, when the heat sink 212 is disposed at the main body 214′, and the cover 214″ covers the main body 214′, the heat exchange medium that flows into the tank 214 from the liquid inlet 214a is difficult to flow out from the aperture between the cover 214″ and the main body 214′ or the aperture between the opening 214c and the heat dissipation base 212a.

As shown in FIG. 3, the heat dissipation device 200 of the embodiment further includes a bracket 260, and the bracket 260 can be disposed at the heat dissipation base 212a via a plurality of fasteners 270. In detail, the fasteners 270, for example, pass through the bracket 260 and the heat dissipation base 212a to assemble the bracket 260 to the heat sink 212. In this way, the first heat dissipation unit can be firmly fixed on the heat source via the bracket 260 to effectively dissipate the heat of the heat source. In other embodiment, the bracket 260 also may be assembled to the first heat dissipation unit in other appropriate mode, or it can be integrated with the tank 214, and it is not limited in the invention.

To sum up, in the invention, the heat sink is disposed in the tank for containing the heat exchange medium and is used to dissipate the heat of a heat source. The heat dissipation base of the heat sink passes through the opening of the tank and is adapted to contact with the heat source. In this way, when the heat exchange medium flows through the heat sink, it can effectively dissipate the heat that is transmitted from the heat source to the heat sink. Furthermore, since the heat sink of the invention is an extrusion heat sink having a plurality of fins or a heat sink having a large heat dissipation area, the heat exchange medium can effectively exchange heat with the heat sink further to allow the heat dissipation device of the invention to have preferred heat dissipation performance.

In the invention, the impeller also is disposed in the tank, and therefore, the heat exchange medium is driven by the impeller to uniformly flow through the heat sink further to effectively dissipate the heat that is transmitted to the heat sink from the heat source. Furthermore, the impeller of the invention also allows the heat exchange medium to have a great flow rate when the heat exchange medium flows through the heat sink. In this way, the heat sink has preferred heat dissipation performance in a unit interval, and the heat dissipation device also has the preferred heat dissipation performance.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A heat dissipation device for dissipating heat of a heat source, the heat dissipation device comprising:
a first heat dissipation unit including:
a heat sink having a heat dissipation base; and
a tank for containing a heat exchange medium, wherein the tank has a liquid inlet, a liquid outlet and an opening, the heat sink is disposed in the tank, and the heat dissipation base is tightly-fitted with the opening and contacts the heat source to dissipate the heat of the heat source; and
a second heat dissipation unit;
a pump; and
a plurality of tubes for connecting the liquid inlet, the liquid outlet, the second heat dissipation unit and the pump to form a closed circulation flow loop, wherein the pump drives the heat exchange medium to flow in the closed circulation flow loop, and the second heat dissipation unit is adapted to cool the heat exchange medium.

2. The heat dissipation device according to claim 1, wherein the first heat dissipation unit further comprises an impeller for driving the heat exchange medium that flows into the tank from the liquid inlet to uniformly flow through the heat sink.

3. The heat dissipation device according to claim 1, wherein the tank comprises a main body and a cover, the heat sink is disposed in the main body, and the cover covers the main body.

4. The heat dissipation device according to claim 3, wherein the tank further comprises a first seal disposed between the cover and the main body.

5. The heat dissipation device according to claim 1, wherein the tank further comprises a second seal disposed between the opening and the heat dissipation base.

6. The heat dissipation device according to claim 1, wherein the second heat dissipation unit is a heat exchanger.

7. The heat dissipation device according to claim 6, further comprising a fan disposed at the second heat dissipation unit.

8. The heat dissipation device according to claim 1 further comprising a bracket and a plurality of fasteners, wherein the fasteners pass through the bracket and the heat dissipation base to allow the bracket to be assembled to the first heat dissipation unit, and the first heat dissipation unit is fixed on the heat source via the bracket.

9. A heat dissipation device for dissipating heat of a heat source, the heat dissipation device comprising:
a heat sink having a heat dissipation base; and
a tank for containing a heat exchange medium, wherein the tank has a liquid inlet, a liquid outlet and an opening, the heat sink is disposed in the tank, the heat exchange medium is adapted to flow into the tank from the liquid inlet, flow through the heat sink and flow out of the tank from the liquid outlet, the heat dissipation base is tightly-fitted with the opening and contacts heat source to dissipate the heat of the heat source.

10. The heat dissipation device according to claim 9, wherein the heat dissipation device further comprises an impeller for driving the heat exchange medium that flows into the tank from the liquid inlet to uniformly flow through the heat sink.

11. The heat dissipation device according to claim 9, wherein the tank comprises a main body and a cover, the heat sink is disposed in the main body, and the cover covers the main body.

12. The heat dissipation device according to claim 11, wherein the tank further comprises a first seal disposed between the cover and the main body.

13. The heat dissipation device according to claim 9, wherein the tank further comprises a second seal disposed between the opening and the heat dissipation base.

14. The heat dissipation device according to claim 9 further comprising a bracket and a plurality of fasteners, wherein the fasteners pass through the bracket and the heat dissipation base to allow the bracket to be assembled to the first heat dissipation unit, and the first heat dissipation unit is fixed on the heat source via the bracket.
